(19) United States
(12) Patent Application Publication
(10) Pub. No.: US 2026/0350269 A1
(43) Pub. Date: Nov. 5, 2026

(54) METHOD FOR PREDICTING AN ITEM OF INFORMATION ON THE FRICTION OF A RUNWAY, AND CORRESPONDING SYSTEM

(71) Applicants: SAFRAN, PARIS (FR); SAFRAN LANDING SYSTEMS, VELIZY-VILLACOUBLAY (FR)

(72) Inventors: Benoît Antoine Yves MARTY, Moissy-Cramayel (FR); Augustin Patrick Alexandre CLOIX, Moissy-Cramayel (FR); Sabrina IKHLEF, Moissy-Cramayel (FR)

(73) Assignees: SAFRAN, PARIS (FR); SAFRAN LANDING SYSTEMS, VELIZY-VILLACOUBLAY (FR)

(21) Appl. No.: 19/484,760

(22) PCT Filed: May 15, 2024
(86) PCT No.: PCT/FR2024/050620

§ 371 Date: Jan. 15, 2026

(30) Foreign Application Priority Data
May 15, 2023 (FR) FR2304812

(51) Int. Cl. G06F 30/27; G08G 5/54

(52) U.S. Cl. CPC G06F 30/27; G08G 5/54

(57) ABSTRACT

A method for predicting information on the friction of an aircraft landing runway, the method including, for a given point in time: obtaining runway context data, obtaining historical friction information data for the runway, comprising data that are all older than the given point in time, predicting using a prediction model configured to receive, as input, at least the context data for the given point in time and the historical friction information data, and to deliver predicted friction information for the runway at the given point in time.

### TECHNICAL FIELD

The invention relates to the general field of aircraft runway management, and in particular to the prediction of runway friction.

Prior art. Knowledge of friction, or more precisely of a coefficient of friction, has become increasingly critical for traffic management within airports, or more precisely for the management of airports and their runways.

Moreover, having information on the state of the landing runway, such as its friction, means that landings can be optimised, thereby reducing the carbon footprint. Characterising runway conditions, enables the environmental performance of aircraft to be improved.

Furthermore, this friction information is also useful within aircraft for managing an anti-skid braking function. It therefore appears that knowledge of a coefficient of friction or of information relating to friction is also particularly critical for safety reasons.

As might be expected, weather conditions on runways have an impact on friction. The presence of contaminants can also have an impact on friction. It should be noted that these contaminants can either be related to the weather conditions (water, ice, snow, etc.) or independent of these conditions (pollution, particles, rubber, etc.).

While it is conceivable to calculate a coefficient of friction within an aircraft using various measurements, this information is generally not immediately usable by air traffic/airport/runway managers. More specifically, this use is generally only made after landing and after the taxiing phase, and once the data communication means allow the transmission of these data to a remote server.

It is therefore not possible to determine the friction of a runway in real time using the solutions from the prior art.

The invention aims, in particular, to overcome these disadvantages.

### DISCLOSURE OF THE INVENTION

For this purpose, the invention proposes a method for predicting information on the friction of an aircraft landing runway, implemented by a computer system, said method comprising a plurality (n, m) of iterations of the following steps:
a) obtaining (S100) runway context data for a current point in time t,
b) obtaining (S101) historical friction information data for the runway, comprising data that are all older than the given point in time t,
c) predicting (S102) by a prediction model configured to receive, as input, at least said context data and said historical friction information data, and to deliver predicted friction information (μ) for the runway at a given point in time t+dt; the method further comprising:
a step-by-step reconstruction (RP1) of a first portion of a curve of the change in the predicted runway friction information (μ), between a point in time of a last landing of an aircraft on the runway and a point in time of obtaining actual information relating to a friction determined by the aircraft during said landing, each point of the curve corresponding to friction information (μ) predicted during one of the iterations of steps a) to c).

It should be noted that the prediction can be considered as a time-related prediction.

Thus, the invention proposes to use a prediction model that delivers friction information for a point in time for which historical friction information data is not necessarily yet available. This makes it possible to obtain friction information before, for example, downloading data acquired when an aircraft passes over the runway, and to monitor friction on the runway in real time. Finally, since the friction information is accessible in real time, it can be used to implement runway management (i.e. management of said runway and optionally other runways at the same airport).

The historical friction information data and the context data may be older than the given point in time, for example older according to a selected time step. For example, from the data known at t, the friction information is predicted at t+dt if dt is the time step.

It should be noted that historical friction information data and context data may be used which are included within a time window extending between t and t−dt′, dt′ being either a time step equal to dt or a different time step.

The step-by-step reconstruction can be implemented with a given time step, said time step being determined, for example, according to a sampling step for one of the data used as input by the prediction model. This time step may be the prediction time step (a prediction is made for a point in time spaced apart from the last date of the time step data).

The method can be implemented by a computer system (one or more computers), for example a remote computer system. This is due, in particular, to the fact that the historical friction information data are older than the point in time for which the prediction is being made; it is not necessary to have information relating to the landing/taxiing of an aircraft on the runway in real time, which takes a long time to transfer.

The friction information may be a coefficient of friction, for example a time average of a coefficient of friction, and/or, for example, a coefficient of friction representative of the runway. Alternatively, the friction information can be a set of friction coefficients, for example each associated with a location on the runway.

The historical friction information data may be of the same type as the friction information to be determined or of a different type.

The runway context data can be chosen from a group of data comprising a value representative of precipitation, a number of landings on the runway during a given period, a value representative of wind, a value representative of humidity, etc. A person skilled in the art will know how to select these context data from this group, or even select other context data, particularly if these other context data are available in real time, i.e. accessible/known for a prediction for the point in time for which the method is being implemented. Context data are chosen, in particular, if they have an impact on or are linked to friction.

The prediction model can also be selected by a person skilled in the art according to the application.

According to one particular embodiment, subsequent to the last landing of an aircraft on the runway, the prediction is implemented for a given point in time between a point in time of said landing (for example its start) and a point in time of obtaining actual information relating to the friction determined by the aircraft during said landing.

A person skilled in the art will know how to identify the point in time at which actual information relating to the friction determined by the aircraft during landing is obtained. In particular, the actual information is not predicted and is obtained, for example, following a transfer of the information determined by the aircraft during landing.

Obtaining this information corresponds, for example, to it being obtained by the computer system that implements the present method; in this sense, a person skilled in the art knows how to identify this actual, non-predicted information. This obtaining may correspond to the display of the information on a computer system screen.

For example, the point in time at which the information is obtained may be after the following periods: taxiing of the aircraft (for example between 5 and 25 minutes), physical transfer of the data (a few minutes via a communication network), and a frequency chosen for grouping and transferring the data (this frequency may be selected by the airline).

In this particular embodiment, it is not necessary to wait to obtain information coming from the last aircraft to have landed on the runway, in order to estimate friction information (this information being obtained by the entity implementing the method remotely from the aircraft). Then, the friction information can even be used for maintenance operations on the runway.

According to a particular embodiment, subsequent to the last landing of an aircraft on the runway, the prediction is further implemented for a point in time subsequent to the point in time of obtaining actual friction information determined by the aircraft during the landing (thus, there is another prediction for this subsequent point in time), the obtaining of the runway context data comprising a prediction of the runway context data.

In this particular implementation, the runway context data are predicted. This can be done, for example, with weather predictions. The context data obtained by prediction may be similar to the context data described above. However, they are obtained from a predictive model and so a person skilled in the art will choose context data that can be predicted, for example if predictive models are available. As a guide, data relating to wind and humidity are usually predicted.

It should be noted that a prediction may be necessary if the context data are not yet available for the given point in time, even though this point in time is in the past, due to the time taken to transfer the context data (typically a few minutes).

Also, in this embodiment, prediction may be limited by using a point in time that is prior to the expiry of a given duration.

According to a particular embodiment, a second portion of the curve of the change in the predicted friction information of the runway is reconstructed step by step, starting from the point in time of obtaining actual information relating to the friction, determined by the aircraft during the landing (and, for example, the point in time of expiry of the given duration).

According to a particular embodiment, the predicted friction information is compared with a given threshold, and an alert signal is generated as a function of the result of the comparison.

This alert signal can be an audible or visual signal, for example configured to be returned to runway management operators.

According to a particular embodiment, the predicted friction information comprises a coefficient of friction associated with the runway, or comprises a set of coefficients of friction, each of the coefficients of said set preferably being associated with a location on the runway.

It should be noted that the historical friction information data may also comprise friction coefficients associated with the runway, or comprise sets of friction coefficients, each of the coefficients in said sets preferably being associated with a location on the runway.

In one particular implementation, the prediction model is a model that can be trained by machine-learning.

Typically, the model can be an artificial neural network executed by a computer system.

A person skilled in the art will know how to select a type of model that can be trained by learning, and will be able, for example, to adapt the number of input neurons of the model according to the dimensions of the input data of the model.

The prediction model is preferably a long short-term memory (LSTM) model.

Alternatively, a recurrent neural network (RNN) model can be used.

According to a particular embodiment, the method comprises a prior learning phase of the prediction model in which historical friction information data (typically so-called actual data, obtained during aircraft landings with sensors) and runway context data previously obtained for a first point in time are used, the learning being configured to increase a similarity between an output of the model and a prior friction information value, for a second point in time spaced apart from the first point in time by a given time step (the output of the model and the prior value each corresponding to the second point in time).

The invention also provides a system for predicting aircraft landing runway friction information, the system comprising:
a module for obtaining runway context data, configured to obtain runway context data for a current point in time t,
a module for obtaining historical friction information data, configured to obtain historical friction information data for the runway, comprising data all older than the current point in time t,
a module for prediction by a prediction model, configured to receive, as input, at least said context data and said historical friction information data, and to deliver predicted friction information for the runway at a given point in time t+dt; the system further comprising:
a module for step-by-step reconstruction (RP1) of a first portion of curve of the change in the predicted friction information (μ) of the runway, between a point in time of a last landing of an aircraft on the runway and a point in time of obtaining actual information relating to a friction determined by the aircraft during said landing, each point on the curve corresponding to friction information (μ) predicted by said prediction module at different points in time.

This system can be configured to implement all the embodiments of the method as described above.

The invention also provides a computer program comprising instructions for executing the method steps of a method as defined above, when said program is executed by a computer.

It should be noted that the computer programs mentioned in the present disclosure can use any programming language, and be in the form of source code, object code, or code that is intermediate between source code and object code, such as in a partially compiled form, or in any other desirable form.

The invention also provides a computer-readable storage medium on which is stored a computer program comprising instructions for executing the steps of a method as defined above.

The recording media referred to in the present disclosure may be any entity or device capable of storing the program. For example, the medium may comprise storage means, such as a ROM, for example a CD ROM or a microelectronic circuit ROM, or even a magnetic recording means, for example a floppy disc or a hard drive.

On the other hand, the recording media may correspond to a transmissible medium such as an optical or electrical signal, which can be routed via an electrical or optical cable, by radio or by other means. In particular, the program according to the invention can be downloaded on an Internet-type network.

Alternatively, the recording media may correspond to an integrated circuit in which the program is incorporated, the circuit being suitable for executing or for being used in the execution of the method in question.

### BRIEF DESCRIPTION OF THE DRAWINGS

Other features and advantages of the present invention will become apparent from the description given below, with reference to the appended drawings which illustrate an exemplary embodiment that is in no way limiting. In the figures:

FIG. 1 is a schematic representation of the steps of a method for predicting friction information according to one example.

FIG. 2 is a schematic representation of steps comprising the method of FIG. 1.

FIG. 3 illustrates a machine learning phase for the friction model.

FIG. 4 is a coefficient of friction curve obtained according to an exemplary implementation of the method for predicting friction information.

FIG. 5 shows a system for predicting friction information according to one example.

### DESCRIPTION OF THE EMBODIMENTS

A method for predicting friction information for an aircraft landing runway will now be described.

This method can be implemented for any point in time (for example, a past point in time, the present, or a future point in time). In particular, this method can be implemented when friction information coming from the last aircraft to land on the runway is not yet available, this information only being transferred to remote servers at a later stage, which delays its availability to runway managers. Here, the method can provide runway friction information to runway managers at any point in time, who can then provide this information to air traffic managers. It is in this sense that the friction information is useful for optimised air traffic management.

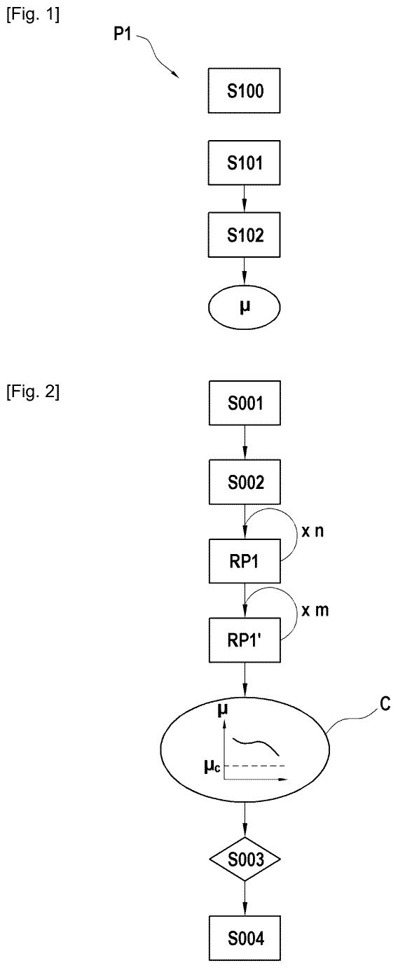

FIG. 1 schematically shows the steps in a method P1 for predicting runway friction information for a given point in time. The friction information is a prediction of the friction at that point in time.

This method can be implemented by a computer system, as will be described in more detail with reference to FIG. 5.

In a first step S100, runway context data are obtained. If the given point in time is in the past, these context data may be the result of observations, and if the given point in time is in the future, these context data may be the result of a prediction. The runway context data can be selected from a group of data comprising a value representative of precipitation, a number of landings on the runway during a given period, a value representative of wind, a value representative of humidity, etc.

In a second step S101, historical friction information data are obtained for the runway, comprising data that are all older than the given point in time. This data can result from aircraft landing and taxiing on the runway (measurements made during these phases provide friction information). Alternatively, this historical data may, for example, result in part from an earlier implementation of the method P1.

The historical friction information data may be of the same type as the predicted friction information obtained using method P1. The term “historical” shall mean that they relate to one or more points in time earlier than the given point in time targeted by the method.

Finally, in a step S102, a prediction is implemented by a prediction model configured to receive as input at least the context data and the historical friction information data, and to deliver predicted friction information for the runway at the given point in time.

The prediction model is, for example, of the long short-term memory (LSTM) type.

Here, the model delivers a predicted friction information value denoted μ, representative of the friction on the runway. For example, if the data from steps S100 and S101 were associated with a point in time t, the prediction may be associated with a point in time t+dt, where dt is a selected time step.

FIG. 2 shows how the method P1 described with reference to FIG. 1 can be implemented, for example in a runway or air traffic management context.

The first stage, S001, designates the phase during which aircraft landed on the runway in question. During these landings followed by taxiing, friction data were acquired in a manner known per se.

In a second step S002, friction information are obtained from the data acquired in step S001. It should be noted that, for each aircraft, the actual (i.e. not predicted) friction information are obtained from data acquired (e.g. by sensors) after the actual aircraft information has been obtained by the entity implementing the method described here (e.g. a computer system). It should be noted that the information transferred from the aircraft can be either friction information or friction-related data from which friction information can be obtained.

It should be noted that the determination of friction in an aircraft is known per se. For example, U.S. Pat. No. 10,202,204 describes obtaining information about friction within an aircraft.

Next, a step-by-step reconstruction of a curve of the change in the runway friction information between the last landing of an aircraft on the runway and the point in time of obtaining actual information can be implemented (the time T1 since the last landing has not expired). This is implemented by repeating the steps of method P1 of FIG. 1, the repetition being designated by the reference RP1. In order to obtain a curve for the period T1 with time step dt, n repetitions are implemented. For each repetition, historical friction information data partly estimated by the previous repetition is used (in other words, friction information predicted or obtained from landings preceding the one targeted here), and context data at the current time of the repetition.

It should be noted that T1 may typically be between 30 minutes and 6 hours, and depends, as indicated above, on the duration of the landing and taxiing, and the duration of one or more data transfers to a server (optionally with pre-processing), until the data is obtained by the entity implementing the method.

After the reconstruction of the curve for the entire period T1, it is possible to move on to a further reconstruction step designated by reference sign RP1′, in which, for a given duration T2, a first friction information curve portion will be reconstructed. For example, for a method which is implemented at the expiry of the period T1 for which repetitions RP1 were implemented up until this expiry, observed context information was used during these repetitions RP1. For the RP1′ repetitions, predicted (and therefore not observed) context information is used as input. In order to obtain a second portion of the curve for the period T2 with a time step dt, m repetitions are implemented.

It should be noted that T2 can typically be between 30 minutes and 2 hours. For example, T2 can be selected by runway management operators, according to the application. A short duration T2, for example, makes it possible to predict more reliable information.

In the figure, the friction information curve, reconstructed after implementation of steps RP1 and RP1′, is denoted C.

In step S003, the predicted friction information obtained at the given point in time, for example illustrated on the curve C, is compared with a given warning threshold μ_{C} visible in the figure. If the predictive friction information reaches the threshold, then an alert signal is generated during step S004, which can be returned to runway managers.

As an indication, a plurality of thresholds may be used, each associated with the generation of an alert signal linked to a specific maintenance action to be carried out on the runway (inspection, snow removal, spreading of de-icing agent).

The one or more thresholds are preferably predetermined and fixed. They can be fixed during an observation phase of the operations carried out for a runway on the basis of real friction information values, for example.

As mentioned above, the prediction model used can be of the LSTM type, and therefore be a model that can be trained by machine learning.

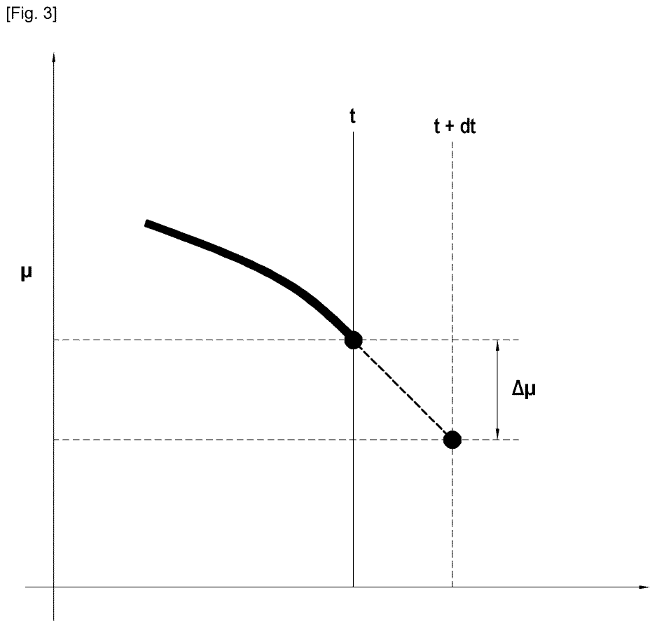

FIG. 3 illustrates a machine learning phase for the friction information prediction model, for which a real friction information curve obtained beforehand (for example over a period of the order of one year) is used. In an individual step of this learning phase, a point in time t is considered, and the model output is obtained for the point in time t+dt, i.e. a second point in time. The comparison between the model output and the actual value of the friction information at t+dt enables learning to be implemented.

Here, the model is configured to predict, for friction information at a point in time t (either a single piece of friction information or a time window that precedes t and includes multiple pieces of friction information), the friction information at point in time t+dt. The duration dt may be equal to the duration of the time window of the data used, or dt may differ from this duration.

Any appropriate cost function and backpropagation could be used to then train the model using a distance between the model output and the actual value at t+dt.

It should be noted that it is possible, during the learning phase of the model, to implement a validation step of the model by comparing actual and predicted values.

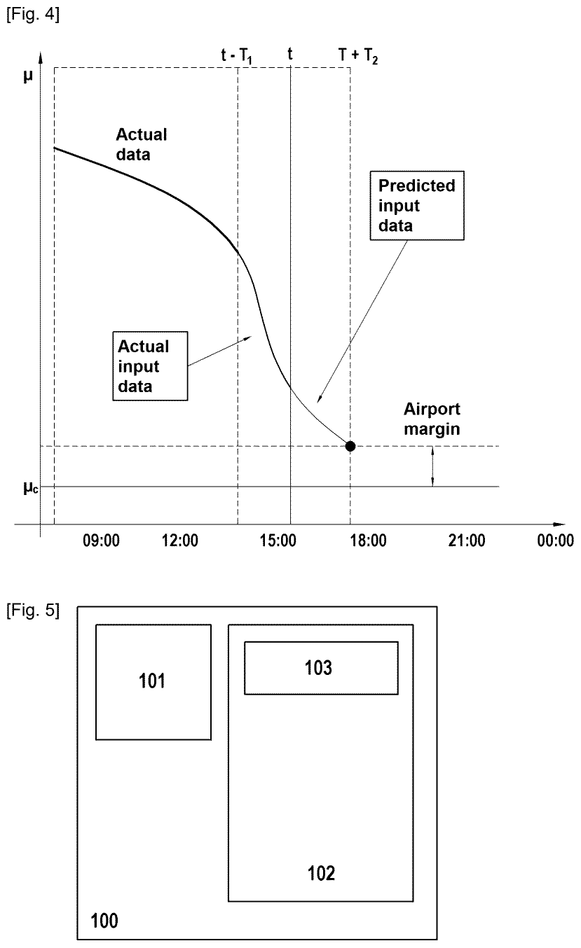

FIG. 4 shows in more detail the curve obtained after implementing repetitions RP1 and RP1′, i.e. after implementing the prediction method. The curve shown in FIG. 4 is obtained after the learning phase described with reference to FIG. 3.

At this stage, it is understood that it is possible to continuously establish friction information curves for a runway. Optionally, sliding average processing can be used to monitor a change in the friction information, for example over windows of a plurality of flights (number of flights between 3 and 20, for example) or over time windows (from 1 hour to 4 hours). Here, the curve remains above a given alert threshold μ_{c} visible in the figure, compared with the predictive friction information. Thus, in this example, no alert signal is sent.

This information can also be used by an airport to anticipate interventions on the runway. For example, different thresholds can be used to trigger different actions (inspection, snow clearance, spreading of de-icing agent).

FIG. 5 is a schematic representation of a system 100 which is a computer system configured to implement the method described above with reference to FIG. 1.

This computer system 100 comprises a processor 101 and a non-volatile memory 102. A computer program 103 is stored in the non-volatile memory. The computer program 103 includes instructions for executing the steps of a method as described above.

Thus, during the execution of the program, the processor 101 and the computer program form:
a module for obtaining runway context data at a given point in time,
a module for obtaining historical friction information data for the runway, comprising data that are all older than the given point in time,
a module for prediction by a prediction model configured to receive, as input, at least the context data for the given point in time and the historical friction information data,
and to deliver a prediction of the friction information for the runway at the given point in time.

The embodiments described above make it possible to improve runway management, in particular in terms of monitoring the condition of a runway.

In addition, the embodiments described above make it possible to obtain knowledge of friction (or grip) as perceived by an aircraft, with its level, variability and change over time.

In particular, the method enables friction information to be obtained continuously, in order to optimise on-runway interventions.

For example, the method can even be used to measure the effectiveness of chemicals applied to runways, or to compare friction levels between airports and the variability of friction.

This method can be applied in airport management and runway management, and can be useful for airlines.

1. A method for predicting information on the friction of an aircraft landing runway, implemented by a computer system, said method comprising a plurality of iterations of the following steps:
a) obtaining runway context data for a current point in time t,
b) obtaining historical friction information data for the runway, comprising data that are all older than the given point in time t,
c) predicting using a prediction model configured to receive, as input, at least said context data and said historical friction information data, and to deliver predicted friction information μ for the runway at a given point in time t+dt; the method further comprising:
a step-by-step reconstruction of a first portion of a curve of the change in the predicted runway friction information μ, between a point in time of a last landing of an aircraft on the runway and a point in time of obtaining actual information relating to a friction determined by the aircraft during said landing, each point on the curve corresponding to friction information μ predicted during one of the iterations of steps a) to c).

2. The method according to claim 1, wherein, subsequent to the last landing of an aircraft on the runway, the prediction is further implemented for a point in time subsequent to the point in time of obtaining actual information relating to the friction determined by the aircraft during said landing, the obtaining of the runway context data comprising a prediction of the runway context data.

3. The method according to claim 2, wherein a second portion of a curve of the change in the runway friction information is reconstructed step by step, starting from the point in time at which actual information relating to the friction determined by the aircraft during landing is obtained.

4. The method according to claim 1, wherein the predicted friction information is compared with a given threshold μ_{c}, and an alert signal is generated as a function of the result of the comparison.

5. The method according to claim 1, wherein the predicted friction information comprises a coefficient of friction associated with the runway, or comprises a set of coefficients of friction, each of the coefficients of said set preferably being associated with a location on the runway.

6. The method according to claim 1, wherein the prediction model is a model that can be trained by machine-learning, the method comprising a prior learning phase of the prediction model in which historical friction information data and runway context data previously obtained for a first point in time are used, the learning being configured to increase a similarity between an output of the model and a prior friction information value, for a second point in time spaced apart from the first point in time by a given time step.

7. A system for predicting aircraft runway friction information, the system comprising:
a module for obtaining runway context data, configured to obtain runway context data for a current point in time t,
a module for obtaining historical friction information data, configured to obtain historical friction information data for the runway, comprising data all older than the current point in time t,
a module for prediction by a prediction model, configured to receive, as input, at least said context data and said historical friction information data, and to deliver predicted friction information for the runway at a given point in time t+dt; the system further comprising:
a module for step-by-step reconstruction of a first portion of curve of the change in the predicted friction information μ of the runway, between a point in time of a last landing of an aircraft on the runway and a point in time of obtaining actual information relating to a friction determined by the aircraft during said landing, each point on the curve corresponding to friction information μ predicted by said prediction module at different points in time.

8. A computer program comprising instructions for executing the steps of a method according to claim 1 when said program is executed by a processor.
